(19) United States
(12) Patent Application Publication
(10) Pub. No.: US 2010/0143849 A1
(43) Pub. Date: Jun. 10, 2010

(54) SEMICONDUCTOR DEVICE MANUFACTURING METHOD

(76) Inventors: Tatsuhiko Ema, Oita-ken (JP); Yuriko Seino, Kanagawa-ken (JP); Shinichi Ito, Kanagawa-ken (JP); Hirokazu Kato, Fishkill, NY (US)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/631,463

(22) Filed: Dec. 4, 2009

(30) Foreign Application Priority Data
Dec. 5, 2008 (JP) 2008-310948

(51) Int. Cl. G03F 7/20

(52) U.S. Cl. 430/319

(57) ABSTRACT

A semiconductor device manufacturing method includes: forming a foundation film on a semiconductor wafer; after forming the foundation film, forming a reaction layer of the semiconductor wafer and the foundation film therebetween; removing the foundation film and leaving the reaction layer on the semiconductor wafer; forming a resist film on the reaction layer; patterning the resist film; and using the patterned resist film as a mask to perform processing on the semiconductor wafer.

### CROSS-REFERENCE TO RELATED APPLICATIONS

This application is based upon and claims the benefit of priority from the prior Japanese Patent Application No. 2008-310948, filed on Dec. 5, 2008; the entire contents of which are incorporated herein by reference.

### BACKGROUND OF THE INVENTION

1. Field of the Invention

This invention relates to a semiconductor device manufacturing method.

2. Background Art

Single layer resist patterning is a process for patterning a resist without using an anti-reflection coating immediately below the resist. One of the problems in single layer resist patterning is that developing or rinsing liquid penetrates into the interface between the resist pattern and the wafer, and that the resist pattern peels off due to, for instance, surface tension of the rinsing liquid. In particular, resist peeling is likely to occur when the material of the wafer surface is soluble in water.

Typically, the wafer surface is hydrophobized to increase adhesiveness between the wafer and the resist. One of the hydrophobizing treatments is to expose the surface to a vapor atmosphere of HMDS (hexamethyldisilazane) (e.g., JP-A-2002-124578(Kokai)).

Currently, with the increasing performance and complexity of semiconductor devices, the number of film types to be patterned using resists is ever increasing. Also in single layer resist processes, stable patterning performance is required for every film type. However, for water-soluble films in particular, even the HMDS treatment cannot sufficiently prevent developing and rinsing liquid from penetrating into the interface between the resist and the wafer.

### SUMMARY OF THE INVENTION

According to an aspect of the invention, there is provided a semiconductor device manufacturing method including: forming a foundation film on a semiconductor wafer; forming a reaction layer of the semiconductor wafer and the foundation film between the semiconductor wafer and the foundation film after forming the foundation film; removing the foundation film and leaving the reaction layer on the semiconductor wafer; forming a resist film on the reaction layer; patterning the resist film; and using the patterned resist film as a mask to perform processing on the semiconductor wafer.

According to another aspect of the invention, there is provided a semiconductor device manufacturing method including: forming a foundation film on a semiconductor wafer; removing the foundation film while leaving a portion of the foundation film as an adhesive layer on the semiconductor wafer; forming a resist film on the adhesive layer; patterning the resist film; and using the patterned resist film as a mask to perform processing on the semiconductor wafer.

### BRIEF DESCRIPTION OF THE DRAWINGS

FIGS. 1A to 1C are schematic views showing relevant steps in a semiconductor device manufacturing method according to a first embodiment of the invention;

FIGS. 2A and 2B are schematic views following FIG. 1C;

FIGS. 3A and 3B are schematic views following FIG. 2B;

FIG. 4 is schematic view showing relevant steps in a semiconductor device manufacturing method according to a second embodiment of the invention;

FIGS. 5A to 5C are schematic views showing relevant steps in a semiconductor device manufacturing method according to a third embodiment of the invention;

FIG. 6 is a schematic view showing shape degradation of an anti-reflection coating, the degradation occurring during development of the resist film in the state where the non-photosensitive developer-soluble anti-reflection coating is formed between the semiconductor wafer and the resist film; and

FIGS. 7A to 7C are schematic views showing the formation mechanism of the reaction layer in the semiconductor device manufacturing method according to the first embodiment of the invention.

### DETAILED DESCRIPTION OF THE INVENTION

Embodiments of the invention will now be described with reference to the drawings.

### First Embodiment

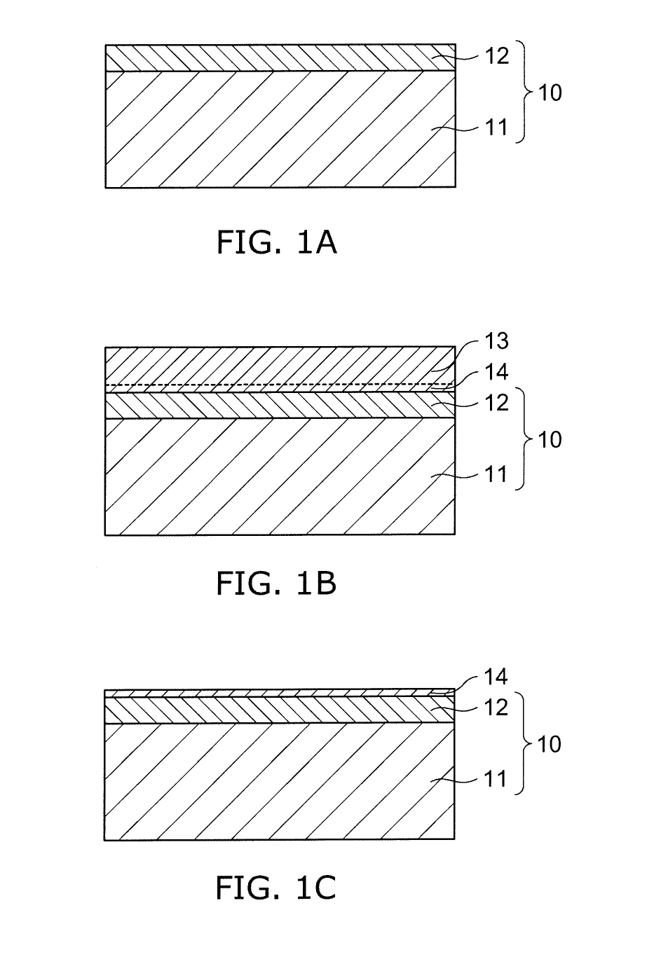

FIGS. 1 to 3 show relevant steps in a semiconductor device manufacturing method according to a first embodiment of the invention.

FIG. 1A shows a semiconductor wafer 10 in this embodiment. In this embodiment, the semiconductor wafer 10 is composed of a substrate 11 and a subject film 12 formed thereon. For instance, the substrate 11 is a silicon substrate, and the subject film 12 is a silicon oxide film (SiO₂ film). The silicon oxide film is formed to a thickness of approximately 10 nm illustratively by sputtering.

Next, as shown in FIG. 1B, a foundation film 13 is formed on the subject film 12 using a coater/developer system. In this embodiment, the foundation film 13 is illustratively made of a non-photosensitive developer-soluble material having anti-reflection capability. The material is applied in a liquid state onto the subject film 12 by spincoating, and subsequently baked at 160° C. for 90 seconds, for instance, to remove its solvent component. Thus, a foundation film 13 having a thickness of 50 nm is obtained. In this baking treatment, by interaction between the subject film 12 and the foundation film 13, a reaction layer 14 of these layers is formed at the interface between the subject film 12 and the foundation film 13. This reaction layer 14 is very thin, such as approximately 2 nm. This reaction layer 14 is an organic layer containing carbon.

Next, the foundation film 13 is removed by wet processing. Specifically, the developing unit in the coater/developer system is used to perform development using an alkaline developer for 30 seconds to remove the foundation film 13. The aforementioned reaction layer 14 is insoluble in this developer, and left thinly on the subject film 12 as shown in FIG. 1C. Alternatively, the foundation film 13 can be removed by etch-back using dry etching.

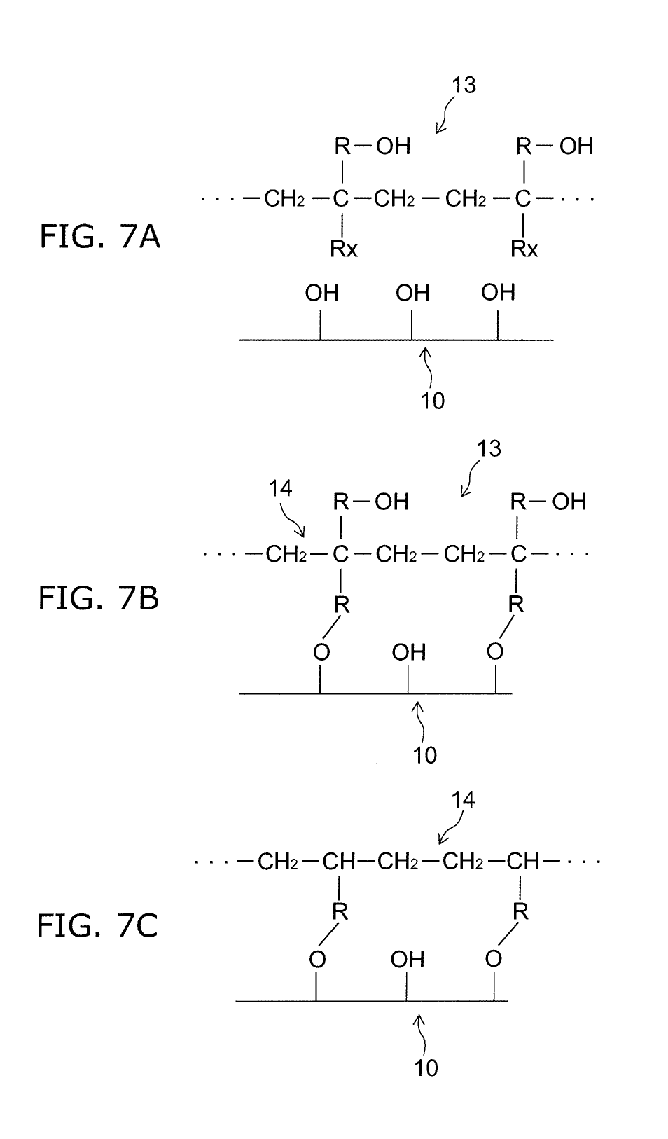

FIGS. 7A to 7C are schematic views of an example formation mechanism of the reaction layer 14 in structural formulas. Here, R is functional group.

FIG. 7A shows the situation where the foundation film 13 is applied onto the surface (hydrophilic surface of a silicon oxide film or the like) of the semiconductor wafer 10. FIG. 7B shows the subsequent situation after the baking treatment. By the removal of the foundation film 13, hydrophilic groups R—OH are removed from above the surface of the semiconductor wafer 10, and as shown in FIG. 7C, a reaction layer 14 made of a thin organic layer is left on the surface of the semiconductor wafer 10.

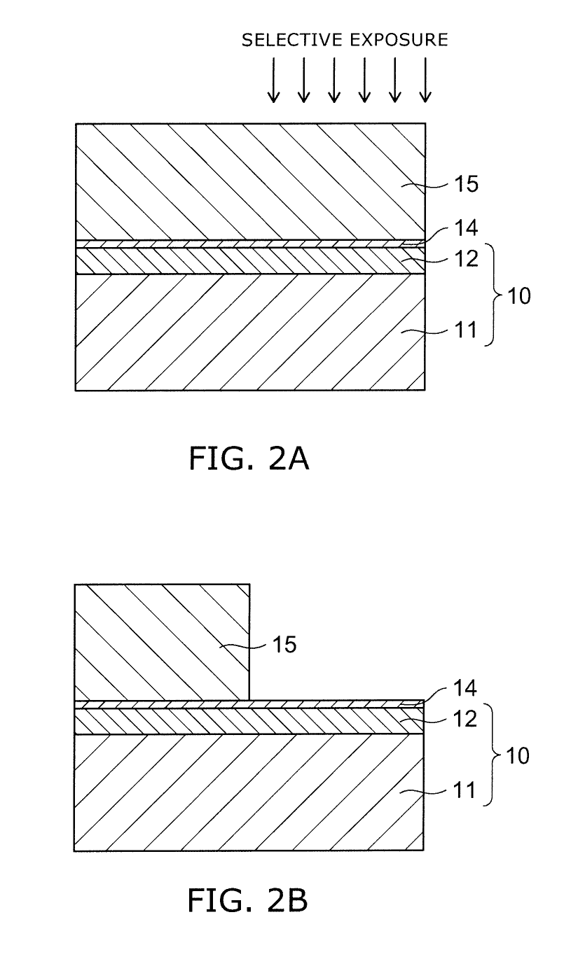

Next, as shown in FIG. 2A, a resist film 15 is formed to a thickness of e.g. 300 nm on the reaction layer 14. This resist film 15 is a chemically amplified positive resist which, upon exposure, generates acid and becomes soluble in developer.

Next, the resist film 15 is selectively irradiated with (exposed to) light using a reticle, not shown, and then developed by an alkaline developer. Thus, the resist film 15 is selectively removed as shown in FIG. 2B. That is, by exposure of the resist film 15, its portion where acid has been generated becomes soluble in developer and is removed.

When the resist film 15 is developed, the underlying reaction layer 14 is insoluble in the developer. Thus, as shown in FIG. 2B, also after the development of the resist film 15, the reaction layer 14 remains on the entire surface of the subject film 12. Here, the resist film 15 remaining after development is highly adhesive to the reaction layer 14 illustratively made of a carbon-containing organic layer, and furthermore, the reaction layer 14 is hydrophobic. Thus, it is difficult for developing or rinsing liquid to penetrate into the interface between the resist film 15 and the reaction layer 14. Hence, the resist film 15 can be prevented from peeling when it is developed and rinsed.

The inventors performed the aforementioned process to pattern the resist film 15 into a line-and-space pattern with a half pitch of 200 nm, and confirmed that the pattern of the resist film 15 was stably formed on the entire surface of the subject film 12 without peeling.

Here, as a possible method for increasing the adhesiveness of the resist film 15 to its foundation to prevent peeling, it may also be considered to leave the foundation film 13 intact on the subject film 12 without removal and form a resist film 15 on the foundation film 13, followed by exposure and development of the resist film 15.

One of the films formed below the resist film 15 and being highly adhesive to the resist film 15 and readily available at present is an anti-reflection coating. The current mainstream anti-reflection coating formed below the resist (bottom anti-reflection coating, BARC) is a non-photosensitive developer-soluble anti-reflection coating. The reason for this is that it exhibits low chemical interaction with the resist and hence, advantageously, can be used substantially independent of resists.

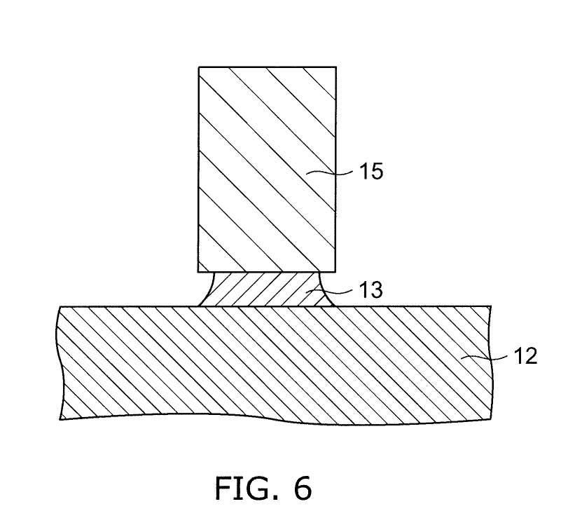

However, the non-photosensitive developer-soluble anti-reflection coating is soluble in the developer for resist development also in its non-exposed portion. Hence, if it is left as a foundation film 13 and the resist film 15 is developed, then as shown in FIG. 6, the lateral side of the portion below the non-exposed resist film 15 is also laterally etched. Thus, the foundation film 13 is thinned and may fail to stably support the resist film 15, and there is concern that the resist film 15 may collapse or peel from above the subject film 12.

In contrast, in this embodiment, even if a non-photosensitive developer-soluble anti-reflection coating is used as a foundation film 13, as described above, the foundation film 13 is removed, thinly leaving only the reaction layer 14 resulting from reaction with the subject film 12. Then, a resist film 15 is formed on the reaction layer 14 and, in this state, subjected to exposure and development. Hence, there is no case where the layer below the resist film 15 is thinned as shown in FIG. 6. Thus, the resist film 15 can be stably adhered to the subject film 12 via the reaction layer 14 as thin as several nm.

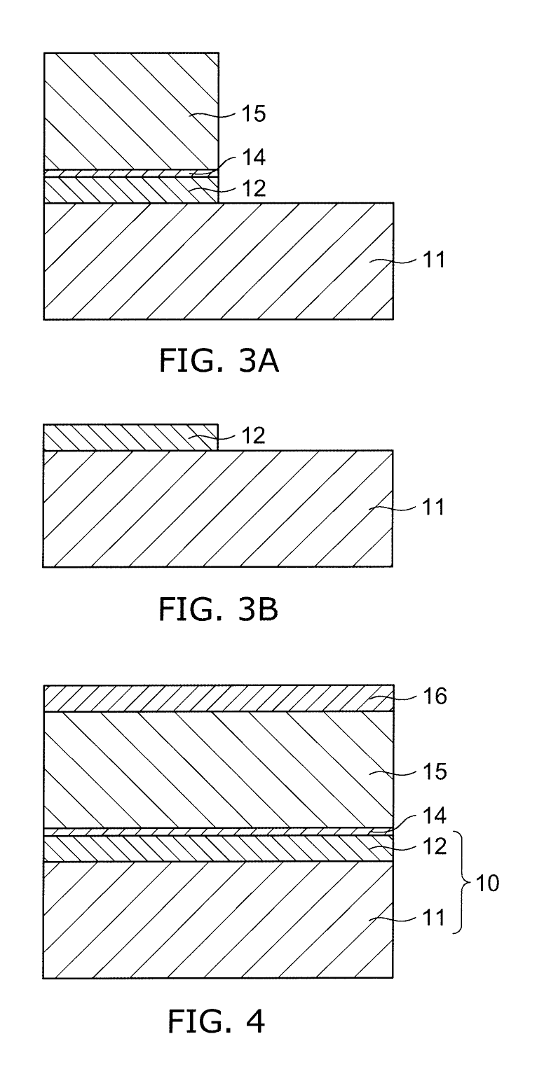

After the resist film 15 is patterned as shown in FIG. 2B, the remaining resist film 15 is used as a mask to perform wet processing to selectively remove the exposed reaction layer 14 and the subject film 12 therebelow, thereby patterning the subject film 12 (FIG. 3A).

Next, the resist film 15 and the reaction layer 14 therebelow are removed (FIG. 3B), and the subject film 12 left on the substrate 11 is used as a mask to perform various processes, such as ion implantation and wet processing, on the substrate 11.

### Second Embodiment

FIG. 4 shows a relevant step in a semiconductor device manufacturing method according to a second embodiment of the invention.

In this embodiment, like the above first embodiment, the steps up to forming the resist film 15 on the reaction layer 14 are performed. Then, an anti-reflection coating 16 (top anti-reflection coating, TARC) is formed to a thickness of e.g. 40 nm on the resist film 15. With the anti-reflection coating 16 formed, the resist film 15 is patterned by exposure and development performed thereon.

In this embodiment, by forming the anti-reflection coating 16, reflection of exposure light can be reduced to increase the shape accuracy of the resist pattern. On the other hand, also in the case where a non-photosensitive developer-soluble anti-reflection coating as described above is used as a foundation film 13 for forming a reaction layer 14, the reaction layer 14 has, although slightly, anti-reflection capability, and functions as a BARC (bottom anti-reflection coating), which is promising for increasing the shape accuracy of the resist pattern.

In the above first and second embodiment, the subject film 12 is illustratively a silicon oxide film (SiO₂ film). However, it is not limited thereto, but can be an Al₂O₃ film, Si film, or TiN film, for instance.

### Third Embodiment

Next, a description is given of a third embodiment in which the invention is applied to imprint lithography.

Imprint lithography is characterized in that a template, or mold, is brought into contact with a resist so that a reverse pattern of the pattern formed at the template surface is transferred to the resist.

One of the problems in imprint lithography is resist peeling due to insufficient adhesion between the wafer and the resist. This is considered to occur in the case where the adhesiveness between the template and the resist is higher than the adhesiveness between the resist and the wafer when the template is brought into contact with the resist. As solutions thereto, it has been proposed to reduce adhesiveness between the template and the resist by forming a release layer on the template surface, and to increase adhesiveness between the resist and the wafer by providing an adhesive layer between the resist and the wafer.

From many years of experience with development in the field of imprint lithography, the inventors have confirmed that the adhesiveness between the resist and the wafer is particularly low when the wafer surface is a silicon oxide film, and in that case, it is useful to apply an organic film onto the wafer surface to form an adhesive layer. However, the adhesive layer commonly used today has a very small thickness, such as several nm. Hence, there is concern about occurrence of pinhole defects where the film is not applied locally. However, because of its small thickness, the defect is very difficult to detect.

In the mass production field, by regular quality control on dust and thickness of the applied film, the film quality is controlled to be constant. However, for the aforementioned adhesive layer, quality control on application defects is virtually impossible. Hence, it is difficult to achieve a stable defect level, and a solution thereto has been sought.

As a result of diligent investigations, the inventors have found a method for forming an organic resin layer of a little less than 1 nm to several nm without generating pinhole defects and with a stable thickness.

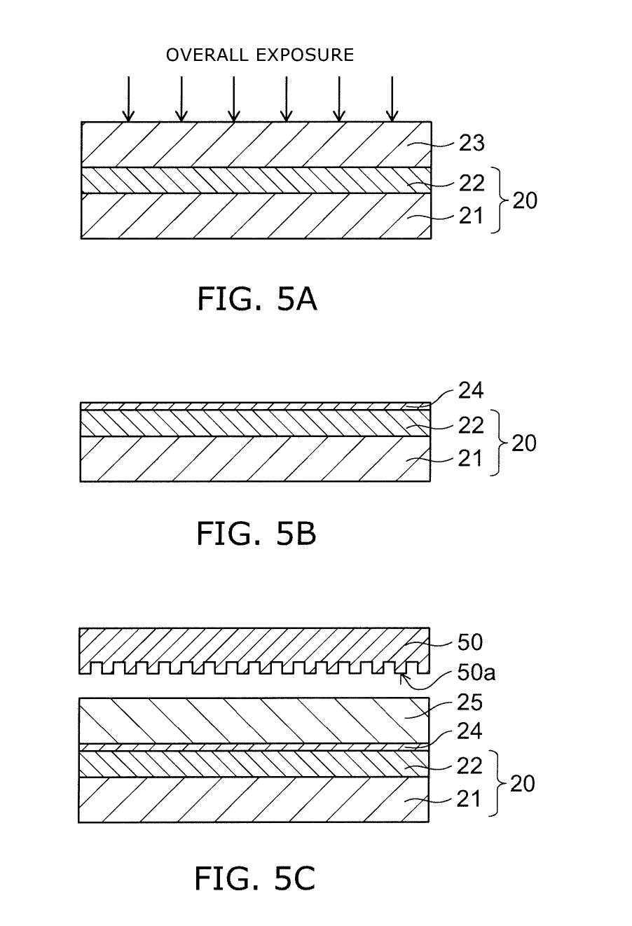

FIG. 5 shows relevant steps in a semiconductor device manufacturing method according to a third embodiment of the invention.

FIG. 5A shows a semiconductor wafer 20 in this embodiment. In this embodiment, the semiconductor wafer 20 is composed of a substrate 21 and a subject film 22 formed thereon. For instance, the substrate 21 is a silicon substrate, and the subject film 22 is a silicon oxide film. The silicon oxide film is formed illustratively by the CVD (chemical vapor deposition) or coating process.

A resist film 23 (first resist) is formed as a foundation film on the subject film 22. This resist film 23 is a chemically amplified positive resist containing an acid-generating agent, which generates acid upon irradiation with exposure light (including electron beams), and a resin component, which becomes soluble in an alkaline developer by the action of the acid. The resist film 23 can be selected in accordance with the exposure light source from among various chemically amplified resists, such as a chemically amplified positive resist for ArF lithography, a chemically amplified positive resist for KrF lithography, and a chemically amplified positive resist for electron beam lithography, which are commonly used.

The inventors have found that the thickness of the thin film functioning as an adhesive layer obtained in the later process varies with the type of this resist film 23. In view of adhesiveness to the resin used in imprint lithography, an appropriate material for the resist film 23 is selected.

The thickness of the resist film 23 does not particularly matter as long as it is in the range from several ten nm to several μm. Quality control on dust and the like of the resist film 23 can be performed using a commercially available optical inspection device, for instance.

Next, the entire surface of the resist film 23 is subjected to exposure. Thus, acid is generated in the resist film 23, and the generated acid is diffused by further performing baking treatment after the exposure. This allows the resist film 23 to be soluble in an alkaline developer.

Then, the resist film 23 is removed using an alkaline developer. At this time, the resist film 23 is not removed completely, but as shown in FIG. 5B, a portion of the resist film 23 on the side in contact with the subject film 22 (this portion being hereinafter referred to as an adhesive layer 24 (or reaction layer)) remains. In this regard, it is considered that the resist film 23 reacts with the subject film (in this embodiment, silicon oxide film) 22 at the interface therebetween to form a film insoluble in the developer for the resist film 23. In other words, the adhesive layer 24 has a lower etching rate in the developer than the resist film 23, exhibiting etching selectivity. The adhesive layer 24 has a very small thickness, such as a little less than 1 nm to several nm, and evenly remains on the entire surface of the subject film 22.

Next, as shown in FIG. 5C, a resist 25 (second resist) is supplied onto the adhesive layer 24. Subsequently, a template 50 with a pattern 50a formed at one surface is pressed in contact with the surface of the resist 25. Furthermore, the resist 25 is cured. Thus, a reverse pattern of the pattern 50a of the template 50 is transferred to the resist 25.

Subsequently, the template 50 is separated from the resist 25. According to this embodiment, the resist 25 is adhered to the semiconductor wafer 20 via the adhesive layer 24 with high adhesion strength. Hence, the resist 25 can be prevented from peeling from the semiconductor wafer 20 when the template 50 is pulled apart.

The adhesive layer 24 is very thin. However, the thin layer is not directly formed on the subject film 22, but as described above, a resist film 23 is formed on the subject film 22 and then removed, consequently leaving an adhesive layer 24 at the interface with the subject film 22. Because the resist film 23 is formed relatively thick, its defect level and thickness can be easily controlled. Hence, the adhesive layer 24 resulting from the resist film 23 can also be formed with high quality, where the defect level is reduced to a certain level or less.

The curing step for the resist 25 in pattern transfer using the template 50 can be performed by a so-called “thermal” process, where the template 50 is pressed to the resist 25 while heating the semiconductor wafer 20 and then, after the temperature of the semiconductor wafer 20 is lowered, the template 50 is separated. Alternatively, the curing step can be performed by a so-called “ultraviolet irradiation” process, where a transparent template 50 is pressed to an ultraviolet curable resist 25 applied in a liquid state, which is cured by ultraviolet irradiation, and then the template 50 is separated.

After the pattern is transferred to the resist 25 as described above, the patterned resist 25 is used as a mask to perform processing (such as dry etching) on the underlying subject film 22, thereby patterning the subject film 22.

The inventors have confirmed that the aforementioned effect is achieved in the case where the silicon substrate surface has a silicon oxide film. However, in the light of the conjectured mechanism by which the adhesive layer 24, a very thin film, is formed, it is considered that a similar effect to the aforementioned one is achieved as long as the subject film 22 is a porous film, besides a silicon oxide film.

The embodiments of the invention have been described with reference to examples. However, the invention is not limited to thereto, but can be variously modified within the spirit of the invention.

In the above first to third embodiment, the semiconductor wafer is illustratively composed of a substrate and a subject film formed on its surface. However, the invention is applicable also to embodiments where the semiconductor wafer is composed only of a substrate. For instance, a foundation film is directly formed on the silicon substrate surface, and a reaction layer is formed at the interface between the substrate surface and the foundation film. Then, the foundation film is removed, and a resist film is formed on the remaining reaction layer. The resist film is patterned to selectively expose the substrate surface, where ion implantation and the like can be performed.

1. A semiconductor device manufacturing method comprising:
forming a foundation film on a semiconductor wafer;
forming a reaction layer of the semiconductor wafer and the foundation film between the semiconductor wafer and the foundation film after forming the foundation film;
removing the foundation film and leaving the reaction layer on the semiconductor wafer;
forming a resist film on the reaction layer;
patterning the resist film; and
using the patterned resist film as a mask to perform processing on the semiconductor wafer.

2. The method according to claim 1, wherein the foundation film is soluble in a developer used in patterning the resist film.

3. The method according to claim 1, wherein the foundation film has anti-reflection capability for exposure light used in patterning the resist film.

4. The method according to claim 1, wherein the foundation film is supplied onto the semiconductor wafer in a liquid state, and then subjected to baking treatment.

5. The method according to claim 4, wherein the baking treatment allows the semiconductor wafer to interact with the foundation film to form the reaction layer.

6. The method according to claim 1, wherein the foundation film is removed by wet processing.

7. The method according to claim 6, wherein the reaction layer is insoluble in a processing liquid used in the wet processing.

8. The method according to claim 1, wherein the reaction layer is an organic layer containing carbon.

9. The method according to claim 1, wherein the reaction layer has anti-reflection capability for exposure light used in patterning the resist film.

10. The method according to claim 1, wherein after the foundation film is removed, the reaction layer remains on the entire surface of the semiconductor wafer.

11. The method according to claim 1, wherein
the patterning the resist film includes performing selective exposure on the resist film and, after the exposure, developing the resist film using a developer, and
the resist film includes an acid-generating agent which generates acid by the exposure, and a portion of the resist film where the acid is generated upon the exposure becomes soluble in the developer and is removed.

12. The method according to claim 1, further comprising:
forming an anti-reflection coating on the resist film after the forming the resist film,
exposure and development being performed on the resist film to pattern the resist film with the anti-reflection coating formed.

13. The method according to claim 1, wherein a surface of the semiconductor wafer is a silicon oxide film.

14. A semiconductor device manufacturing method comprising:
forming a foundation film on a semiconductor wafer;
removing the foundation film while leaving a portion of the foundation film as an adhesive layer on the semiconductor wafer;
forming a resist film on the adhesive layer;
patterning the resist film; and
using the patterned resist film as a mask to perform processing on the semiconductor wafer.

15. The method according to claim 14, wherein
the patterning the resist film includes bringing a template having a feature pattern into contact with the resist film, curing the resist film, and separating the template from the resist film.

16. The method according to claim 14, further comprising:
performing exposure on the entire surface of the foundation film after the forming the foundation film.

17. The method according to claim 16, wherein the foundation film is removed by developing treatment using a developer after the exposure.

18. The method according to claim 17, wherein the adhesive layer is insoluble in the developer.

19. The method according to claim 17, wherein the adhesive layer has a lower etching rate in the developer than the foundation film.

20. The method according to claim 14, wherein the adhesive layer is formed at an interface between the foundation film and the semiconductor wafer by reaction therebetween.
